(19) United States
(12) Patent Application Publication
(10) Pub. No.: US 2014/0111936 A1
(43) Pub. Date: Apr. 24, 2014

(54) ELECTRONIC DEVICE WITH AIRFLOW GUIDE COVER HAVING INTRUSION SWITCH

(71) Applicants: HONG FU JIN PRECISION INDUSTRY (SHENZHEN)CO., LTD., Shenzhen (CN); HON HAI PRECISION INDUSTRY CO., LTD., New Taipei (TW)

(72) Inventors: JUN-HUI WANG, Shenzhen (CN); YU HAN, Shenzhen (CN)

(73) Assignees: Hon Hai Precision Industry Co., Ltd., New Taipei (TW); Hong Fu Jin Precision Industry (ShenZhen)Co., Ltd., Shenzhen (CN)

(21) Appl. No.: 13/868,972

(22) Filed: Apr. 23, 2013

(30) Foreign Application Priority Data
Oct. 19, 2012 (CN) 2012103995258

(51) Int. Cl. H05K 7/14; H05K 7/20

(52) U.S. Cl. CPC H05K 7/1485; H05K 7/20145
USPC 361/690; 165/74

(57) ABSTRACT

An airflow guide cover includes a top wall, a first sidewall and a second sidewall extending down from opposite sides of the top wall, and an intrusion switch. The intrusion switch includes a detection switch mounted to an inner surface of the first sidewall, a connector, and a cable connected between the detection switch and the connector. A through hole is defined in the top wall. A probe capable of moving up and down is mounted on a top of the detection switch and extends through the through hole.

### BACKGROUND

1. Technical Field

The present disclosure relates to an electronic device including an airflow guide cover.

2. Description of Related Art

In a server, an intrusion switch is often mounted to a side board of the server, to detect whether the top board of the server is open or not. However, the cable connected between the intrusion switch and a mother board of the server is thin and is hung on the side board, which is easily abraded by other elements in installing or uninstalling these elements.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an embodiment of an electronic device, wherein the electronic device includes an airflow guide cover, an intrusion switch, and a motherboard.

FIG. 2 is an exploded, isometric view of the airflow guide cover, the intrusion switch, and the motherboard of FIG. 1.

FIG. 3 is an inverted view of the airflow guide cover and the intrusion switch of FIG. 2.

FIG. 4 is an assembled view of FIG. 3.

FIG. 5 is a partially assembled view of FIG. 2.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

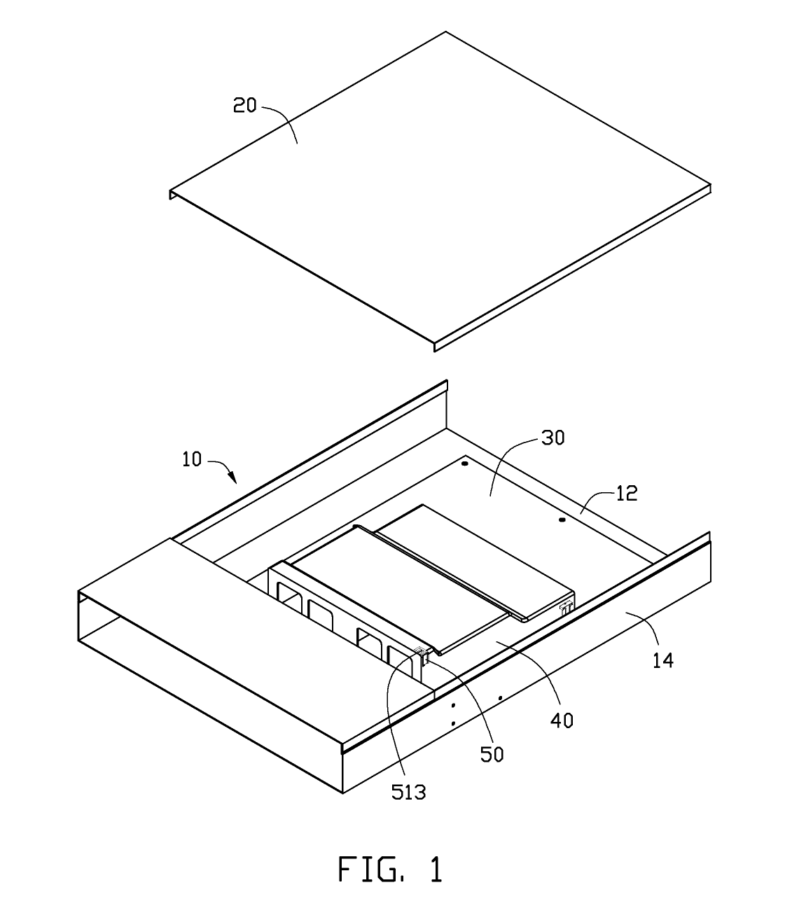

Referring to FIG. 1, an exemplary embodiment of an electronic device includes a base 10, a top board 20 detachably mounted to the base 10, a motherboard 30, and an airflow guide cover 40 mounted on the motherboard 30.

The base 10 includes a bottom board 12 and two side boards 14 perpendicularly extending up from opposite two sides of the bottom board 12. When the top board 20 is mounted to the base 10, a bottom surface of the top board 20 contacts top sides of the side boards 14.

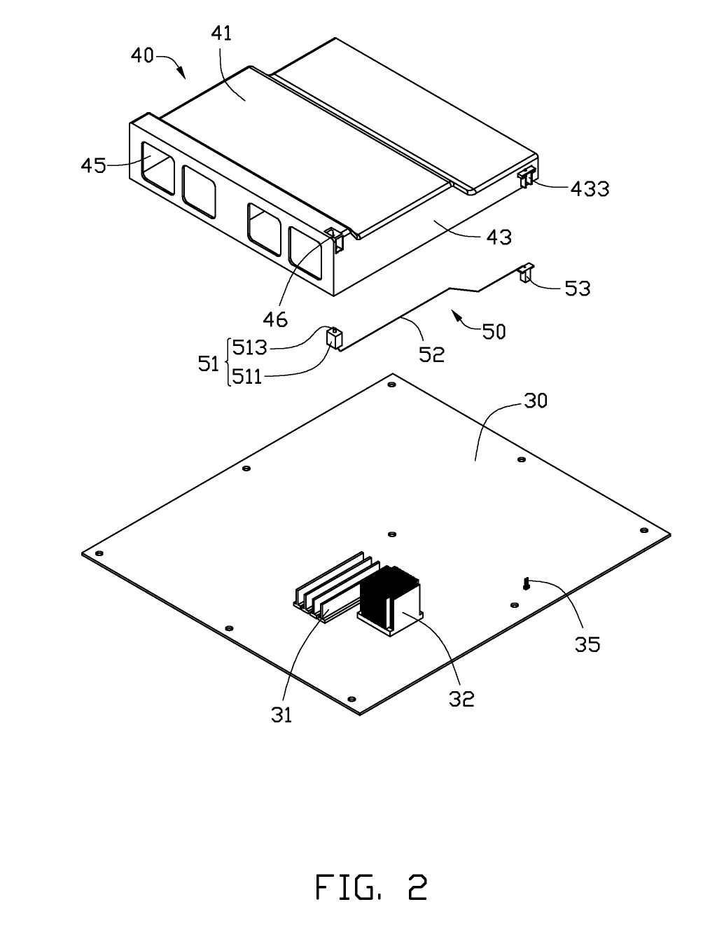

Referring to FIG. 2, the motherboard 30 is mounted on the bottom board 12. A plurality of electronic elements 31, such as expansion cards, and a heat sink 32 are mounted on the motherboard 30. A connector 35 is mounted on the motherboard 30, beside the electronic elements 31 and the heat sink 32.

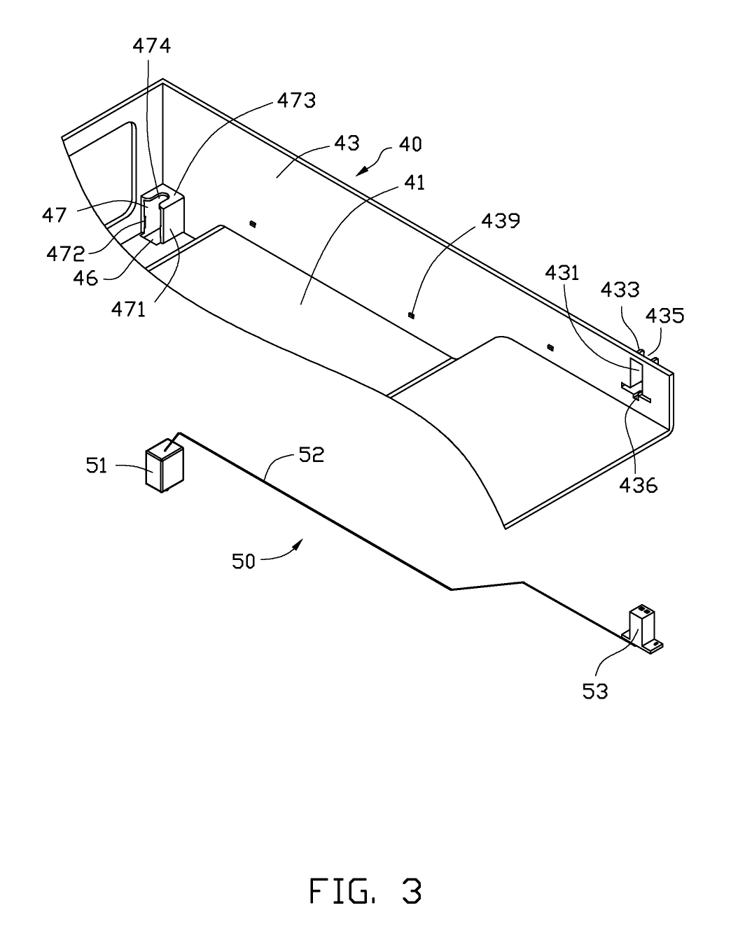

Referring to FIGS. 2 and 3, the airflow guide cover 40 includes a top wall 41, a first sidewall 43 and a second sidewall 45 perpendicularly extending down from opposite sides of the top wall 41, and an intrusion switch 50 mounted to an inner surface of the first sidewall 43.

Two parallel connection pieces 471 are perpendicularly connected between inner surfaces of the top wall 41 and the first sidewall 43. The connection pieces 471 are adjacent to a front end of the airflow guide cover 40. A supporting piece 473 is connected between bottom ends of the connection pieces 471 away from the top wall 41. A receiving space 47 is bounded by the top wall 41, the first sidewall 43, the connection pieces 471, and the supporting piece 473. A through hole 46 communicating with the receiving space 47 is defined in each of the top wall 41 and the first sidewall 43. A protrusion 472 protrudes from an inner surface of a distal end of each connection piece 471 away from the first sidewall 43. A cutout 474 is defined in the supporting piece 473, opposite to the first sidewall 43. A slot 431 is defined in a lower portion of the first sidewall 43 and is adjacent to a rear end of the first sidewall 43 away from the receiving space 47. A resilient receiving portion 433 extends from an outer surface of the first sidewall 43 and surrounds the slot 431. The receiving portion 433 defines an opening 435 in a bottom. A recess 436 is defined in an inner surface of a top of the receiving portion 433, extending through the first sidewall 43. A plurality of hooks 439 extends from the inner surface of the first sidewall 43, between the receiving space 47 and the slot 431.

The intrusion switch 50 includes a detection switch 51, a connector 53, and a cable 52 having a first end connected to a bottom of the detection switch 51 and a second end connected to a top of the connector 53. The detection switch 51 includes a main body 511, and a probe 513 mounted to a top of the main body 511 and movable in a direction from top to bottom.

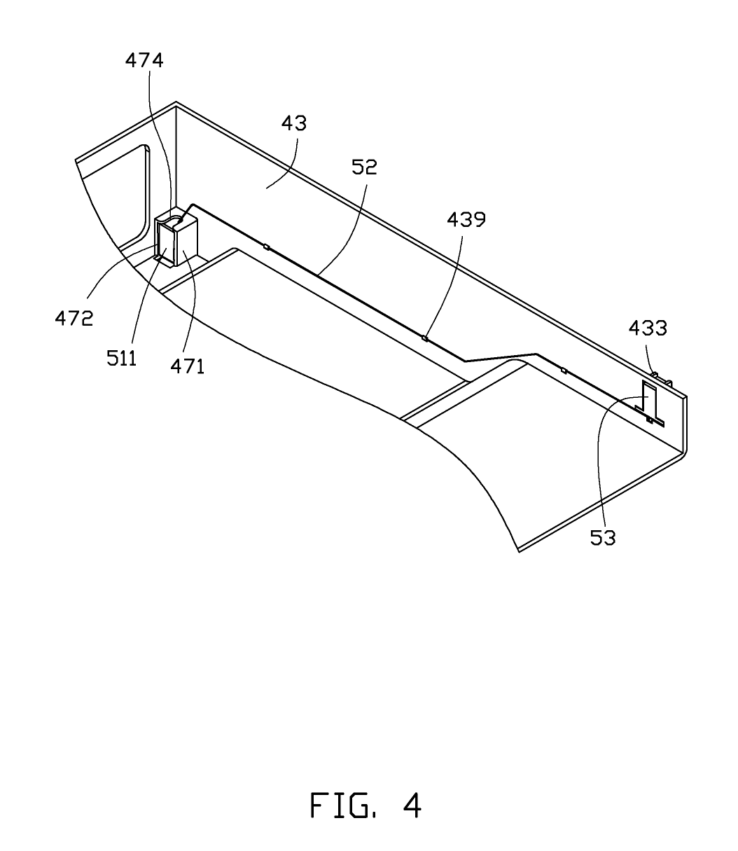

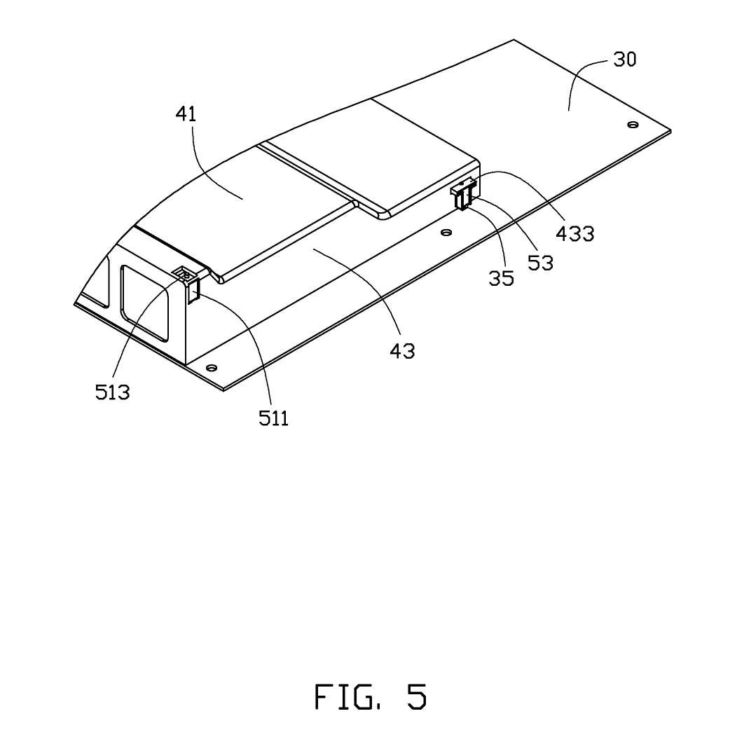

Referring to FIGS. 4 and 5, in assembly, the main body 511 is inserted into the receiving space 47 through a space between the distal ends of the connecting pieces 47. The probe 513 is exposed out of the top wall 41 through the through hole 46 defined in the top wall 41. The protrusions 472 block an outer side of the main body 511 away from the first sidewall 43. The cable 52 extends out of the cutout 474 and is bound by the hooks 439. The connector 53 is extended through the slot 431 and then is fixed in the receiving portion 433. The bottom of the connector 53 is aligned with the opening 435. A portion of the cable 52 adjacent to the connector 53 is received in the recess 436.

The airflow guide cover 40 is then mounted to the motherboard 30, with the electronic elements 31 and the heat sink 32 are enclosed by the airflow guide cover 40, and the connector 35 are connected to the connector 53.

Referring to FIG. 1, a top end of the probe 513 is higher than the side board 14. When the top board 20 is mounted to the base 10 and presses the probe 513 downward, the intrusion switch 50 will send a signal that the top board 20 is mounted to the base 10 to the motherboard 30. In uninstalling the top board 20, the probe 513 is restored to move upward, and the intrusion switch 50 will send another signal that the top board 20 disengages from the base 10 to the motherboard 30.

Because the cable 52 is bound by the hooks 439 of the first sidewall 43, and the first sidewall 43 is spaced from the electronic elements 31 and the heat sink 32, the cable 52 will not being abraded by the electronic elements 31 and the heat sink 32.

It is believed that the present embodiments and their advantages will be understood from the foregoing description, and various changes may be made thereto without departing from the spirit and scope of the description or sacrificing all of their material advantages, the examples hereinbefore described merely being exemplary embodiments.

What is claimed is:

1. An airflow guide cover, comprising:
a top wall defining a through hole;
a first sidewall perpendicularly extending down from a first side of the top wall;
a second sidewall perpendicularly extending down from a second side of the top wall opposite to the first sidewall; and
an intrusion switch mounted to an inner surface of the first sidewall and comprising a detection switch, a connector, and a cable connected between the detection switch and the connector; wherein a probe extends from a top of the detection switch and extends through the through hole, the probe is movable in a direction perpendicular to the top wall.

2. The airflow guide cover of claim 1, wherein a plurality of hooks extends from the inner surface of the first sidewall to bind the cable.

3. The airflow guide cover of claim 1, further comprising two connection pieces connected between inner surfaces of the top wall and the first sidewall, and a supporting piece connected between bottom ends of the connecting pieces away from the top wall; a receiving space is bounded by the top wall, the first sidewall, the connection pieces, and the supporting piece; the through hole is aligned with and communicated with the receiving space, wherein the detection switch comprises a main body received in the receiving space, the probe is mounted to a top of the main body.

4. The airflow guide cover of claim 3, wherein a protrusion protrudes from an inner surface of each connection piece to block a side of the main body of the detection switch away from the first sidewall.

5. The airflow guide cover of claim 1, wherein a slot is defined in the first sidewall, a receiving portion is mounted to an outer surface of the first sidewall and surrounds the slot, the receiving portion defines an opening in a bottom, the connector extends through the slot and is fixed in the receiving portion, a bottom of the connector is aligned with the opening.

6. An electronic device, comprising:
a base comprising a bottom board and two side boards extending up from opposite sides of the bottom board;
a top board detachably mounted to the base to contact top sides of the side boards;
a motherboard mounted on the bottom board, wherein a first connector is mounted on the motherboard; and
an airflow guide cover comprising:
a top wall defining a through hole;
a sidewall perpendicularly extending down from a side of the top wall; and
an intrusion switch mounted to an inner surface of the sidewall and comprising a detection switch, a second connector connected to the first connector, and a cable connected between the detection switch and the second connector; wherein a probe extends from a top of the detection switch and extends through the through hole, the probe is movable in a direction perpendicular to the top wall;
wherein a top end of the probe is higher than the side boards in an original state, wherein the intrusion switch sends a signal that the top board is mounted to the base to the motherboard, in response to the top board is mounted to the base and presses the detection switch; and the intrusion switch is restored up and sends another signal that the top board is disengaged from the base to the motherboard, in response to the top board is disengaged from the base.

7. The electronic device of claim 6, wherein a plurality of electronic elements and a heat sink are mounted on the motherboard, enclosed in the airflow guide cover, and spaced from the sidewall.

8. The electronic device of claim 6, further comprising two connection pieces connected between inner surfaces of the top wall and the first sidewall, and a supporting piece connected between bottom ends of the connecting pieces away from the top wall, a receiving space is bounded by the top wall, the first sidewall, the connection pieces, and the supporting piece; the through hole is aligned with and communicated with the receiving space, wherein the detection switch comprises a main body received in the receiving space, the probe is mounted to a top of the main body.

9. The electronic device cover of claim 8, wherein a protrusion protrudes from an inner surface of each connection piece to block a side of the main body of the detection switch away from the sidewall.

10. The electronic device cover of claim 6, wherein a slot is defined in the sidewall, a receiving portion is mounted to an outer surface of the sidewall and surrounds the slot, the receiving portion defines an opening in a bottom, the connector extends through the slot and is fixed in the receiving portion, a bottom of the connector is aligned with the opening.
